(19) United States
(12) Patent Application Publication
(10) Pub. No.: US 2013/0128466 A1
(43) Pub. Date: May 23, 2013

(54) Backlight Module, Backplane, and LCD Device

(71) Applicants: Yuchun Hsiao, Shenzhen (CN); Yicheng Kuo, Shenzhen (CN); Chong Huang, Shenzhen (CN); Jiahe Cheng, Shenzhen (CN)

(72) Inventors: Yuchun Hsiao, Shenzhen (CN); Yicheng Kuo, Shenzhen (CN); Chong Huang, Shenzhen (CN); Jiahe Cheng, Shenzhen (CN)

(21) Appl. No.: 13/376,181

(22) PCT Filed: Nov. 30, 2011
(86) PCT No.: PCT/CN2011/083262

§ 371 Date: Dec. 3, 2011

(30) Foreign Application Priority Data
Nov. 18, 2011 (CN) 2011103696459

(51) Int. Cl. H05K 7/18; H05K 7/14

(52) U.S. Cl. 361/728; 211/183

(57) ABSTRACT

The present invention discloses a backlight module, a backplane and an LCD device. The backlight module comprises a backplane, a PCB and locking piece(s) for fixing the PCB on the backplane; the backplane comprises a frame formed by multiple brackets, and bridges arranged on the brackets; each bracket or bridge is provided with a chute, and the locking piece is arranged in the chute by a fixed structure at the bottom of the locking piece. Because the backplane comprises a frame formed by multiple brackets, the frame is provided with bridges for arranging PCB and the like, and both the brackets and bridges are formed by combining universal shaped parts, the present invention has the advantages of low manufacturing cost, and material saving; meanwhile, because each bridge is provided with a chute for arranging the hillock, the hillock is fixed in the random position of the chute. Thus, the hillock is arranged in the corresponding position of the chute in accordance with the PCB size, so that the backplane can be adapted for PCBs of different size, or backlight modules or LCD devices with components of different number.

### TECHNICAL FIELD

The present invention relates to the field of liquid crystal displays (LCDs), and more particularly to a backlight module, a backplane, and an LCD device.

### BACKGROUND ART

All the LCD modules produced in batches at present use integral backplanes. Generally, the backplanes are integrally formed in the mode of metal stamping or plastic injection, causing heavy products and high material cost of the products. Large products require large stamping equipment, and then the cost becomes high; the corresponding die size is large, the structure is complicated, and then the die cost is high. FIG. 1 shows a simplified structure diagram of an existing backplane. The backplane is formed by integrally stamping a block of metal, and the backplane surface is stamped with hillocks 80 for fixing a printed circuit board (PCB). The backplane has the disadvantages of more consumed material, heavy weight and complicated manufacturing procedure. With the increasingly fierce market competition, it is more and more important to effectively reduce the design cost. Thus, saving material cost and simplifying assembly technology become the crucial research directions of each designer, and then hollow or joined backplane design is developed on the basis of the original integral backplane design, which reduces the cost to a certain extent. However, the strength of hollow or joined backplanes is reduced, and then it is difficult to fix the PCB originally fixed on backplane on the backplane.

Hillock(s) is a structure which is arranged on the backplane and is used for fixing the PCB and the like. In general, the hillock protrudes the backplane surface, and the PCB is fixed on the hillock by screws or other locking pieces, and then the short circuit caused by direct contact between the PCB and the backplane surface is avoided. An existing backplane is as shown in FIG. 1, and the hillocks 80 on the backplane are integrally stamped and formed on the backplane when the backplane is made. Thus, the positions of the hillocks 80 on the backplane are fixed so it is difficult to adapt for the PCBs of different size; meanwhile, for PCBs of different size and backlight modules requiring components of different number, corresponding backplanes are required to be mold-made; and for PCBs of different size, new backplanes are required to be mold-made. Thus, the generality of backplanes is poor, and the production cost is high under the condition.

### SUMMARY

The aim of the present invention is to provide a backlight module with the advantages of material saving and good generality, a backplane and an LCD device.

The purpose of the present invention is achieved by the following technical schemes. A backlight module comprises a backplane, a PCB and locking piece(s) for fixing the PCB on the backplane; the backplane comprises a frame formed by multiple brackets, and bridges arranged on the brackets; each bracket or bridge is provided with a chute, and the locking piece is arranged in the chute by a fixed structure at the bottom of the locking piece.

Preferably, the chute is provided with a locking piece for fixing the PCB, and the locking piece is arranged in the corresponding position of the chute in accordance with the PCB size. By determining the PCB size, the locking piece is arranged in the corresponding position of the chute. Thus, PCBs of different size can be arranged by the backplane of the same size.

Preferably, the locking piece is a hillock, and the bottom of the hillock is provided with a fixed structure for arranging the hillock in the chute. The hillock has good effect for locking PCB, and avoids the short circuit of PCB circuits.

Preferably, the fixed structure is a threaded hole arranged at the bottom of the hillock. The hillock can be conveniently arranged on the backplane by a screw, and can be removed.

Preferably, the threaded hole penetrates through the hillock. Thus, the PCB, the hillock and the backplane can be mutually fixed by only one screw, and the three components are fixed because the screw passes through the PCB, the hillock and the backplane and is tightly locked by a nut.

Preferably, the fixed structure is a rivet integrally arranged at the bottom of the hillock. The riveting mode has the advantages of simplicity, convenience, quickness and high reliability, and can be accomplished by machinery.

Preferably, the locking piece is an independent mushroom head. The mode for locking PCB by the mushroom head is convenient and quick.

Preferably, the locking piece is arranged on the backplane by a screw, and the locking piece can be moved in the chute. Before arranging the PCB, the locking piece is arranged on the backplane in advance, but is not tightly locked, so that the locking piece can be moved in the chute. Thus, when locking PCBs of different size, the locking piece is moved to the corresponding position; and after locking the PCBs, the locking piece is tightly locked on the backplane. Thus, the installation process becomes quicker without measuring positions in advance.

Preferably, the locking piece is arranged on the backplane by a screw or rivet and is tightly locked, and the locking piece is fixed in the chute. The mode has the advantage of high installation accuracy.

A backplane, the backplane comprises a frame formed by multiple brackets, and bridges arranged on the brackets. Each bracket or bridge is provided with a chute for arranging the locking piece.

An LCD device, the LCD device comprises any one of the aforementioned backlight modules.

Because the backplane comprises a frame formed by multiple brackets, the frame is provided with bridges for arranging PCB and the like, and both the brackets and bridges are formed by combining universal shaped parts, the present invention has the advantages of low manufacturing cost, and material saving; meanwhile, because each bridge is provided with a chute for arranging the hillock, the hillock is fixed in the random position of the chute. Thus, the hillock is arranged in the corresponding position of the chute in accordance with the PCB size, so that the backplane can be adapted for PCBs of different size, or backlight modules or LCD devices with components of different number.

### BRIEF DESCRIPTION OF FIGURES

FIG. 1 is a simplified structure diagram of an existing backplane;

FIG. 2 is a simplified structure diagram of a backplane of example 2 of the present invention;

FIG. 3 is a simplified structure diagram of a bridge of example 2 of the present invention;

FIG. 4 is a simplified structure diagram of one hillock of an example of the present invention;

FIG. 5 is one structure diagram of a PCB locked by a hillock of an example of the present invention;

FIG. 6 is a simplified structure diagram of the other hillock of an example of the present invention;

FIG. 7 is the other structure diagram of a PCB locked by a hillock of an example of the present invention; and

FIG. 8 is a simplified structure diagram of a third hillock of an example of the present invention.

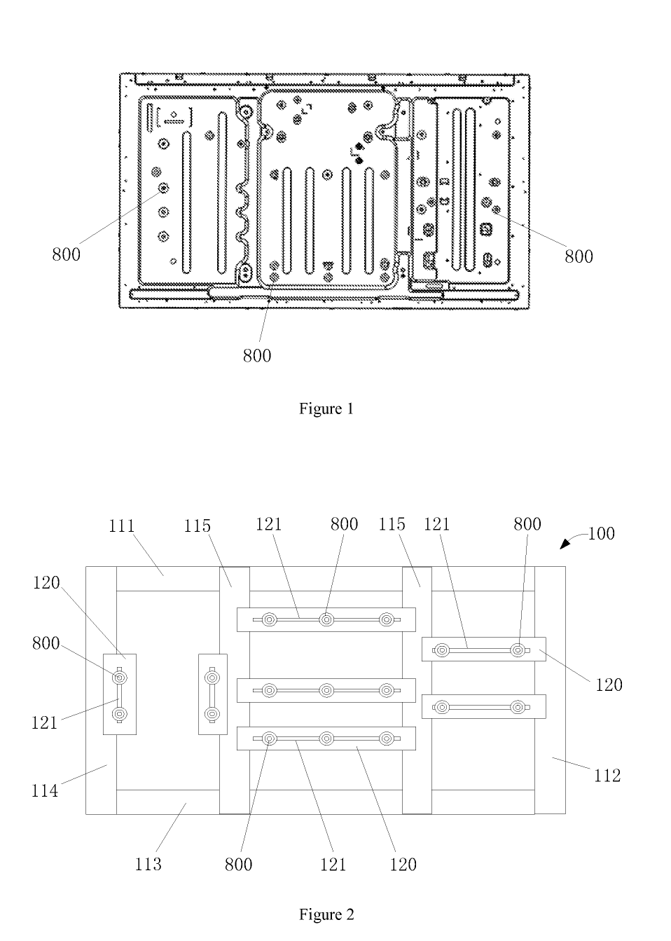

Wherein: 1. backplane; 100. frame; 111. upper bracket; 112. right bracket; 113. lower bracket; 114. left bracket; 115. central bracket; 120. bridge; 121. chute; 800. hillock; 810. threaded hole; 811. screw; 812. nut; 820. rivet; 300. PCB.

### DETAILED DESCRIPTION

An example of the present invention provides an LCD device, comprising an LCD panel and a backlight module. The bottom of the backlight module is provided with a backplane. The backplane comprises a frame formed by multiple brackets. The frame is provided with multiple bridges, and the bridges are used for fixing components of PCBs and other backlight modules. Each bracket or bridge is provided with a chute, and the locking piece such as a hillock and the like for locking the PCB is arranged in the chute by the fixed structure at the bottom of the locking piece.

In accordance with the scheme, the invention will further be described in detail in accordance with the following preferred examples.

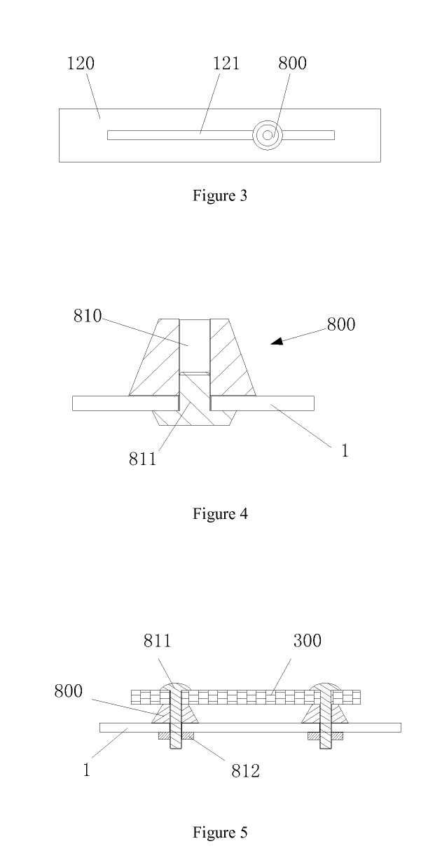

FIG. 2 shows a frame type backplane of the example. The backplane is combined into a main frame 100 by multiple brackets 110 and is combined and fixed on the brackets by matching with corresponding bridges 120. The bracket comprises an upper bracket 111, a lower bracket 113, a left bracket 114 and a right bracket 112 which are connected end to end to form a large frame of the whole backplane; two central brackets 115 are arranged inside the large frame, and both ends of each central bracket 115 are respectively fixed above the upper bracket and the lower bracket. Multiple bridges are arranged on each bracket and between two brackets. The bridges 120 are provided with chutes 121, and hillocks 800 for fixing the PCB and the like are correspondingly arranged on the brackets and the bridges. In the example, the hillocks 800 are hillocks existing as independent parts. As shown in FIG. 2, the main frame 100 of the frame type backplane is provided with multiple bridges 120, each bridge 120 is provided with a chute 121 (FIG. 3 shows the condition of one bridge provided with a hillock 800), and the hillock 800 existing as an independent part is arranged in the chute 121. The position of the hillock 800 is adjusted in accordance with the PCB size, and is adjusted within the chute 121. Thus, the PCB of the size can be locked, and then the backplanes of the type can be generally used in various backlight modules.

In order to facilitate installation, the hillock is arranged in the chute in advance by a screw, but the screw is not tightly locked so that the hillock can be slid in the chute. The hillock is slid in the corresponding position in accordance with the PCB size, and the screw is tightly locked after locking the PCB. Alternatively, the hillock is directly fixed by a screw or a rivet in accordance with the PCB size, and then the PBC is locked to reduce process.

In the example, the chute can be arranged in the bracket as well, and then more positions for arranging hillocks can be provided, to meet some backlight modules with many components.

Of course, the PCB can be locked on the backplane by other similar locking pieces such as mushroom heads and the like besides hillocks. The mushroom heads are made into independent existing parts and are arranged in the chutes as the hillocks, and the PCBs of different size are locked in the same way.

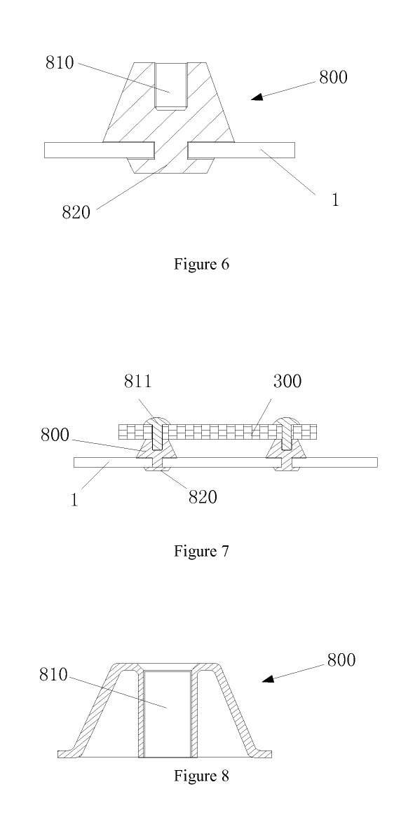

FIG. 4 and FIG. 6 show a hillock 800 existing as an independent part. The hillock is not formed on the backplane when the backplane is manufactured, but the hillock 800 is arranged in the corresponding position of the backplane 1 to achieve the aim of positioning the PCB and the like of different size by flexibly using the hillock 800.

As shown in FIG. 4, the hillock 800 has a threaded hole 810 for arranging and fixing the PCB and the like, and the threaded hole 810 penetrates through the independent hillock 800. Thus, the independent hillock 800 can be fixed on the backplane 1 from the lower part through a screw 811, and can fix the PCB from the upper part. Accordingly, the backplane 1 is provided with hillock mounting holes, namely chutes, of which the size is corresponding to that of the threaded hole 810 of each hillock 800, so that the hillock 800 can be fixed on the backplane. Similarly, the PCB, the hillock and the backplane are fixed by using only one screw matching with a nut. As shown in FIG. 5, because the threaded hole penetrates through the whole hillock 800, the PCB 300 is directly locked on the backplane 1 by a screw 811 matching with a nut 812.

In order to facilitate installation, as shown in FIG. 6, the bottom of the hillock is designed into a structure similar to a rivet, namely the rivet and the hillock are integrally formed. The lower end of the hillock 800 is connected with the backplane 1 by riveting, namely the hillock 800 is riveted on the backplane 1 by a rivet 820. The riveting mode is quicker than the screwing mode, and can be accomplished by machinery so that the production efficiency can be improved.

As shown in FIG. 7, the hillock 800 is fixed on the backplane 1 by a rivet 820, and then the PCB 300 is fixed on the hillock by a screw 811 so that the PCB 300 is locked.

To save material and facilitate processing, the hillock can be formed by directly stamping a panel. As shown in FIG. 8, the inside of the hillock 800 is of a hollow structure, and the whole hillock 800 is made of panel material, which saves material and facilitates production.

Of course, the shape of the independent hillock 800 in the example is not limited to the conical section shape shown in the figure; other shape such as square can also achieve the corresponding purpose.

In the example, corresponding hillocks are arranged in corresponding positions in accordance with the PCB size of the backlight module; meanwhile, the number of corresponding hillocks is set according to PCB components of different number.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A backlight module, comprising: a backplane, a PCB and locking piece(s) for fixing the PCB on the backplane; said backplane comprises a frame formed by multiple brackets, and bridges arranged on said brackets; each said bracket or bridge is provided with a chute, and said locking piece is arranged in said chute by a fixed structure at the bottom of the locking piece.

2. The backlight module of claim 1, wherein said chute is provided with a locking piece for fixing the PCB, and said locking piece is arranged in the corresponding position of the chute in accordance with the PCB size.

3. The backlight module of claim 2, wherein said locking piece is a hillock, and the bottom of said hillock is provided with a fixed structure for arranging the hillock in said chute.

4. The backlight module of claim 3, wherein said fixed structure is a threaded hole arranged at the bottom of the hillock.

5. The backlight module of claim 4, wherein said threaded hole penetrates through the hillock.

6. The backlight module of claim 3, wherein said fixed structure is a rivet integrally arranged at the bottom of the hillock.

7. The backlight module of claim 2, wherein said locking piece is an independent mushroom head.

8. The backlight module of claim 2, wherein said locking piece is fixed on the backplane by a screw, and the locking piece can be moved in the chute.

9. The backlight module of claim 2, wherein said locking piece is fixed on the backplane by a screw or rivet and is tightly locked, and said locking piece is fixed in said chute.

10. A backplane, comprising: a frame formed by multiple brackets, and bridges arranged on said brackets. Each said bracket or bridge is provided with a chute for arranging the locking piece.

11. An LCD device, comprising: the backlight module of claim 1. Said backlight module comprises a backplane, a PCB and locking piece(s) for fixing the PCB on the backplane; said backplane comprises a frame formed by multiple brackets, and bridges arranged on said brackets; each said bracket or bridge is provided with a chute, and said locking piece is arranged in the chute by a fixed structure at the bottom of the locking piece.

12. The LCD device of claim 11, wherein said chute is provided with a locking piece for fixing the PCB, and said locking piece is arranged in the corresponding position of the chute in accordance with the PCB size.

13. The LCD device of claim 12, wherein said locking piece is a hillock, and the bottom of the hillock is provided with a fixed structure for arranging the hillock in the chute.

14. The LCD device of claim 13, wherein said fixed structure is a threaded hole arranged at the bottom of the hillock.

15. The LCD device of claim 14, wherein said threaded hole penetrates through the hillock.

16. The LCD device of claim 13, wherein said fixed structure is a rivet integrally arranged at the bottom of the hillock.

17. The LCD device of claim 12, wherein said locking piece is an independent mushroom head.

18. The LCD device of claim 12, wherein said locking piece is fixed on the backplane by a screw, and the locking piece can be moved in the chute.

19. The LCD device of claim 12, wherein said locking piece is arranged on the backplane by a screw or rivet and is tightly locked, and said locking piece is fixed in said chute.
